(19) United States
(12) Patent Application Publication
(10) Pub. No.: US 2026/0214832 A1
(43) Pub. Date: Jul. 23, 2026

(54) PROCESSING SYSTEM FOR ELECTRONIC DEVICE, INSERTION APPARATUS, PULL-OUT APPARATUS, AND CONNECTION MEMBER

(71) Applicant: WNC Corporation, HSINCHU (TW)

(72) Inventors: PO-YU WANG, HSINCHU (TW); MING-CHAN LEE, HSINCHU (TW); MING-AN LAI, HSINCHU (TW)

(21) Appl. No.: 19/445,843

(22) Filed: Jan. 12, 2026

(30) Foreign Application Priority Data
Jan. 21, 2025 (TW) 114102412

(51) Int. Cl. H05K 7/14

(52) U.S. Cl. CPC H05K 7/1498; H05K 7/1429; H05K 7/1487; H05K 7/1489

(57) ABSTRACT

A processing system for an electronic device, an insertion apparatus, a pull-out apparatus, and a connection member. The processing system includes an insertion apparatus having a transportation device and an insertion device that are disposed adjacent to each other, a processing station, and a pull-out apparatus having a carrying platform and a pull-out device that are disposed adjacent to each other. The transportation device is configured to receive an electronic device, and the insertion device is configured to push and insert a connection member into the electronic device to form an electronic module. The processing station is configured to receive the electronic module and perform a predetermined operation thereon. The carrying platform is configured to receive and hold the electronic module upon completion of the predetermined operation, and the pull-out device is configured to pull the connection member out of the electronic device.

### CROSS-REFERENCE TO RELATED PATENT APPLICATION

This application claims the benefit of priority to Taiwan Patent Application No. 114102412, filed on January 21, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a processing system, and more particularly to a processing system for an electronic device, an insertion apparatus, a pull-out apparatus, and a connection member.

### BACKGROUND OF THE DISCLOSURE

In conventional processing systems, when performing a related operation (for example: an inspection operation) on an electronic device, a connection member needs to be manually inserted into the electronic device so that the internal circuits of the electronic device can be connected and activated through the connection member, thereby enabling the electronic device and the connection member to perform the related operation. However, the conventional processing systems require a large amount of manpower to operate, making it difficult to improve their operational efficiency.

### SUMMARY OF THE DISCLOSURE

Embodiments of the present disclosure provide a processing system for an electronic device, an insertion apparatus, a pull-out apparatus, and a connection member, which can effectively improve possible defects of conventional processing systems.

In one aspect, the present disclosure provides a processing system for an electronic device, which includes an insertion apparatus, a work station, and a pull-out device. The insertion apparatus includes a transportation device, and an insertion device. The transportation device is configured to receive the electronic device and position the electronic device to a pending insertion region. The electronic device includes a plurality of ports. The insertion device is disposed adjacent to the transportation device and includes a supply cassette, an ejecting mechanism, a pushing-in mechanism, and a transfer mechanism. The supply cassette is configured to accommodate a plurality of connection members stacked therein, and a discharge slot is formed at a bottom of the supply cassette and configured to allow one of the connection members to be disposed therein, and each connection member includes a plurality of connectors at a front end thereof and a magnetically attractable portion at a rear end thereof. The ejecting mechanism is disposed corresponding to the discharge slot and configured to push out the connection member disposed in the discharge slot to be located at a pending pick-up position. The pushing-in mechanism is disposed adjacent to the pending insertion region and has a magnetically attractive end facing the pending insertion region. The transfer mechanism is configured to move the connection member located at the pending pick-up position to the pushing-in mechanism and to be attracted and fixed by the magnetically attractive end through the magnetically attractable portion. The pushing-in mechanism is configured to push the connection member attracted thereby toward the pending insertion region to cause the plurality of connectors to be respectively inserted into the plurality of ports, and the electronic device together with the connection member plugged thereon jointly define an electronic module. The work station is located at a downstream of the insertion apparatus and configured to receive the electronic module and perform a predetermined operation on the electronic module. The pull-out apparatus is located at a downstream of the work station and includes a carrying platform, and a pull-out device. The carrying platform is configured to receive and position the electronic module after completion of the predetermined operation. The pulling device is disposed adjacent to the carrying platform and includes a placement mechanism, a receiving cassette, and a pull-out mechanism. The placement mechanism includes a magnetic seat facing the carrying platform. The receiving cassette is disposed below the magnetic seat, and the magnetic seat is movable along the receiving cassette. The pulling mechanism includes a gripper adjacent to the magnetic seat and is configured to hold the connection member of the electronic module through the gripper and move the gripper toward the magnetic seat, so that the connection member is separated from the electronic device and is attracted and positioned on the magnetic seat through the magnetically attractable portion. The magnetic seat is configured to move the connection member attracted thereby toward the receiving cassette so that the connection member is placed into the receiving cassette.

In another aspect, the present disclosure provides an insertion apparatus, which includes: a transportation device and an insertion device. The transportation device is configured to receive an electronic device and position the electronic device to a pending insertion region. The electronic device includes a plurality of ports. The insertion device is disposed adjacent to the transportation device, and includes a supply cassette, an ejecting mechanism, a pushing-in mechanism and a transfer mechanism. The supply cassette is configured to accommodate a plurality of connection members stacked therein, and a discharge slot is formed at a bottom of the supply cassette and configured to allow one of the connection members to be disposed therein. Each connection member includes a plurality of connectors at a front end thereof and a magnetically attractable portion at a rear end thereof. The ejecting mechanism is disposed corresponding to the discharge slot, and configured to push out the connection member disposed in the discharge slot to be located at a pending pick-up position. The pushing-in mechanism is disposed adjacent to the pending insertion region and has a magnetically attractive end facing the pending insertion region. The transfer mechanism is configured to move the connection member located at the pending pick-up position to the pushing-in mechanism and to be attracted and fixed by the magnetically attractive end through the magnetically attractable portion. The pushing-in mechanism is configured to push the connection member attracted thereby toward the pending insertion region to cause the plurality of connectors to be respectively inserted into the plurality of ports.

In yet another aspect, the present disclosure provides a pull-out apparatus, which includes: a carrying platform and a pull-out device. The carrying platform is configured to receive and position an electronic device and a connection member inserted into the electronic device. The connection member includes a magnetically attractable portion at a rear end thereof. The pull-out device is disposed adjacent to the carrying platform, and includes a placement mechanism, a receiving cassette, and a pulling mechanism. The placement mechanism includes a magnetic seat facing the carrying platform. The receiving cassette is disposed below the magnetic seat, and the magnetic seat is movable along the receiving cassette. The pulling mechanism includes a gripper adjacent to the magnetic seat and is configured to hold the connection member of the electronic device through the gripper and move the gripper toward the magnetic seat, so that the connection member is separated from the electronic device and is attracted and positioned on the magnetic seat through the magnetically attractable portion. The magnetic seat is configured to move the connection member attracted thereby toward the receiving cassette so that the connection member is placed into the receiving cassette.

In yet another aspect, the present disclosure provides a connection member, which includes a positioning carrier, a circuit board, and a plurality of connectors. The positioning carrier has a magnetically attractable portion disposed at a rear end. The circuit board is disposed at a front end of the positioning carrier. The plurality of connectors are disposed on the circuit board and arranged in two rows, and any one row of the connectors is electrically coupled to the other row of the connectors through the circuit board. The plurality of connectors of the connection member are configured to be respectively inserted into a plurality of ports of an electronic device.

In summary, by the respective structural configurations of the insertion apparatus and the pull-out apparatus, the processing system for an electronic device of the present disclosure can be positioned upstream and downstream of the work station, respectively, allowing the predetermined operation of the electronic device to be performed through automated plugging and unplugging of the connection member, thereby reducing labor and effectively improving overall operational efficiency.

Further, the insertion apparatus and the pull-out apparatus of the present disclosure can realize automated plugging and unplugging between the electronic device and the connection member through the coordinated arrangement of components, thereby reducing labor and effectively improving overall operational efficiency.

Moreover, the connection member of the present disclosure can, through the cooperation of the plurality of connectors and the circuit board, effectively replace multiple cables adopted by the existing process, facilitating application in automated operations. The connection member is further provided with the magnetically attractable portion for positioning the connection member, which further facilitates the connection member to be applied in automated operations.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic block diagram of a processing system for an electronic device according to an embodiment of the present disclosure;

FIG. 2 is a schematic top view of an insertion apparatus of FIG. 1 when the electronic device is located at a pending insertion region;

FIG. 3 is a schematic perspective view showing a part of FIG. 1;

FIG. 4 is a schematic perspective view from another viewing angle of FIG. 3;

FIG. 5 is a schematic perspective view of a connection member according to an embodiment of the present disclosure;

FIG. 6 is a schematic perspective view from another viewing angle of FIG. 5;

FIG. 7 is a schematic perspective view of a cassette according to an embodiment of the present disclosure;

FIG. 8 is a schematic perspective view from another viewing angle of FIG. 7;

FIG. 9 is a schematic view showing a subsequent operation of an ejecting mechanism of FIG. 4;

FIG. 10 is a schematic view showing a subsequent operation of a transfer mechanism of FIG. 9;

FIG. 11 is a schematic view showing a subsequent operation of the transfer mechanism of FIG. 10;

FIG. 12 is a schematic view showing a pushing-in mechanism of FIG. 11 attracting the connection member;

FIG. 13 is a schematic view showing a subsequent operation of the pushing-in mechanism of FIG. 12;

FIG. 14 is a schematic perspective view of a pull-out apparatus of FIG. 1 receiving an electronic module;

FIG. 15 is a schematic view showing a pulling mechanism of the pull-out apparatus of FIG. 14 holding the connection member;

FIG. 16 is a schematic view showing the pulling mechanism of FIG. 15 moving the connection member to a placement mechanism;

FIG. 17 is a schematic view showing the placement mechanism of FIG. 16 moving one connection member to a receiving cassette;

FIG. 18 is a schematic view of a subsequent operation of FIG. 17;

FIG. 19 is a schematic view of a subsequent operation of FIG. 18;

FIG. 20 is a schematic view showing the placement mechanism of FIG. 16 moving another connection member to the receiving cassette;

FIG. 21 is a schematic view of a subsequent operation of FIG. 19; and

FIG. 22 is a schematic view of the pull-out apparatus according to an embodiment of the present disclosure during replacement when the receiving cassette is filled with connection members.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In addition, the term “or”, as used herein, should include any one or a combination of the associated enlisted items, as the case may be. The term “connect” in the context of the present disclosure means there is a physical connection between two elements and is directly or indirectly connected. The term “couple” in the context of the present disclosure means there is no physical connection between two separated elements, and the two elements are instead connected by their electric field energy where the electric field energy generated by the current of one element excites the electric field energy of the other element.

### [Embodiment]

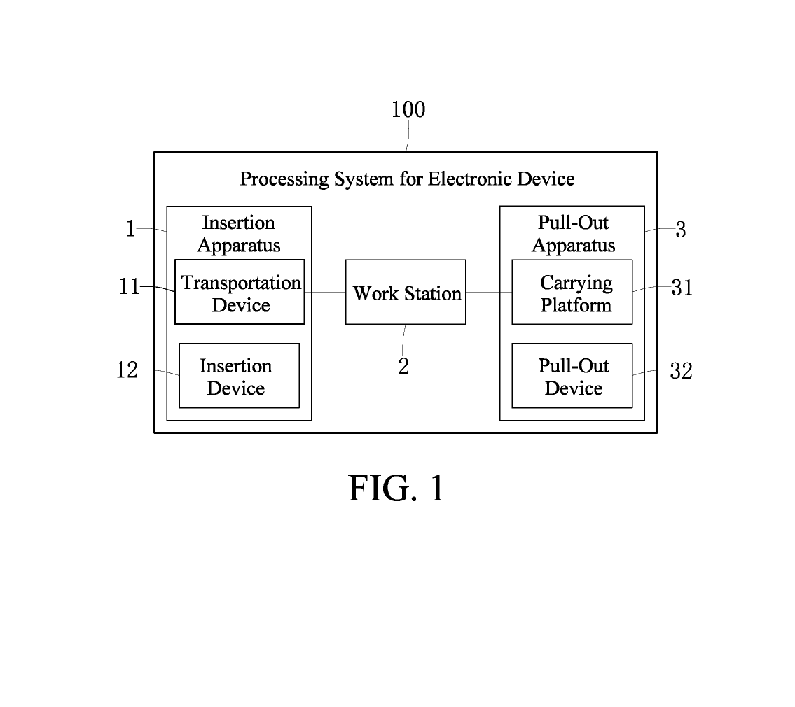

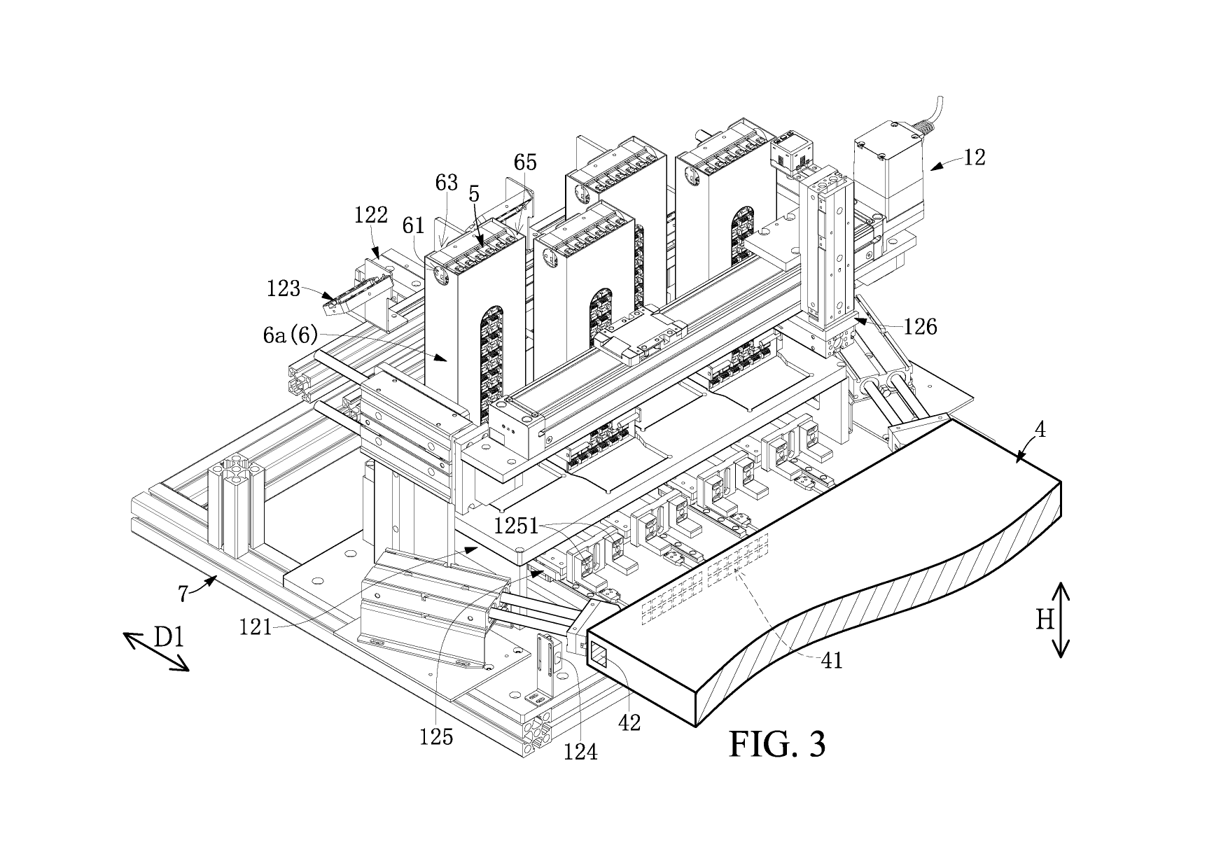

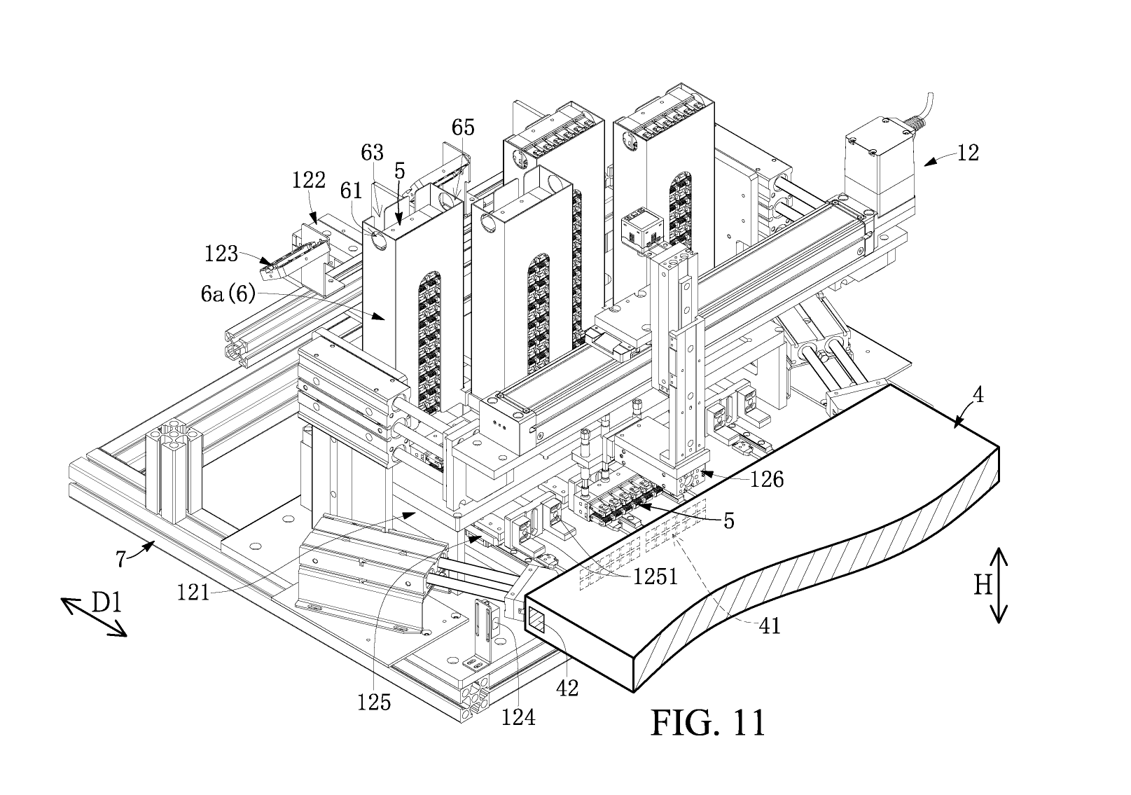

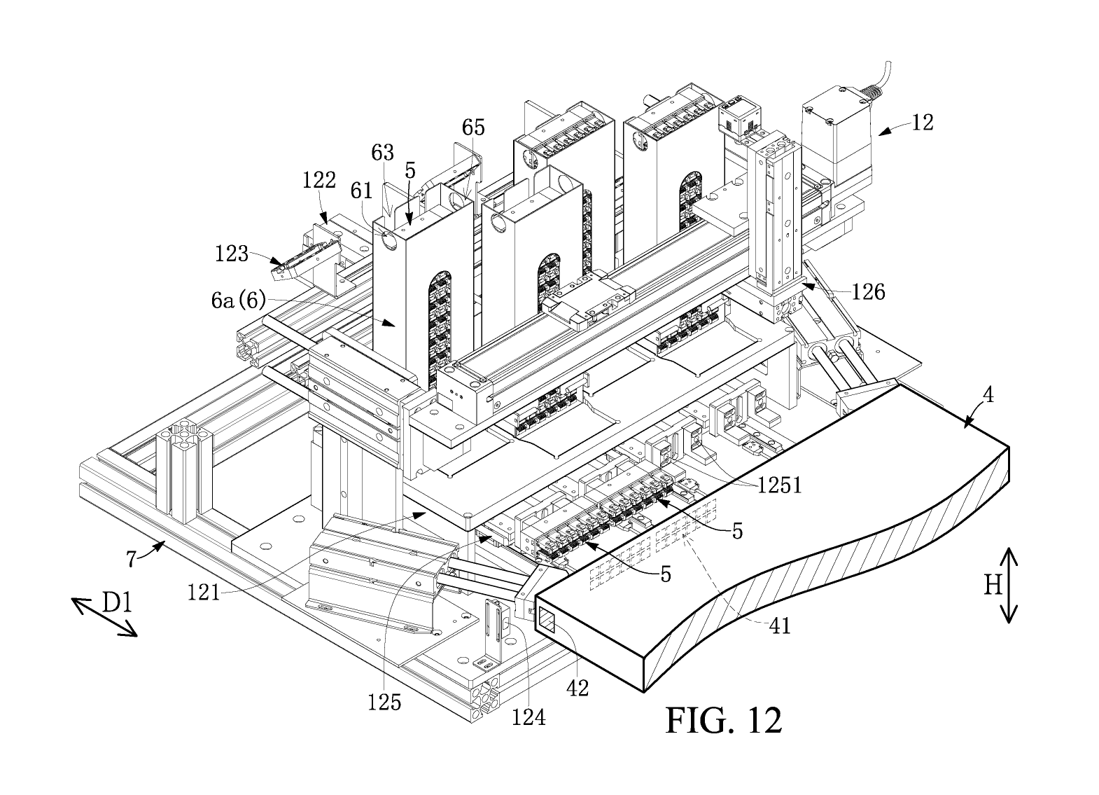

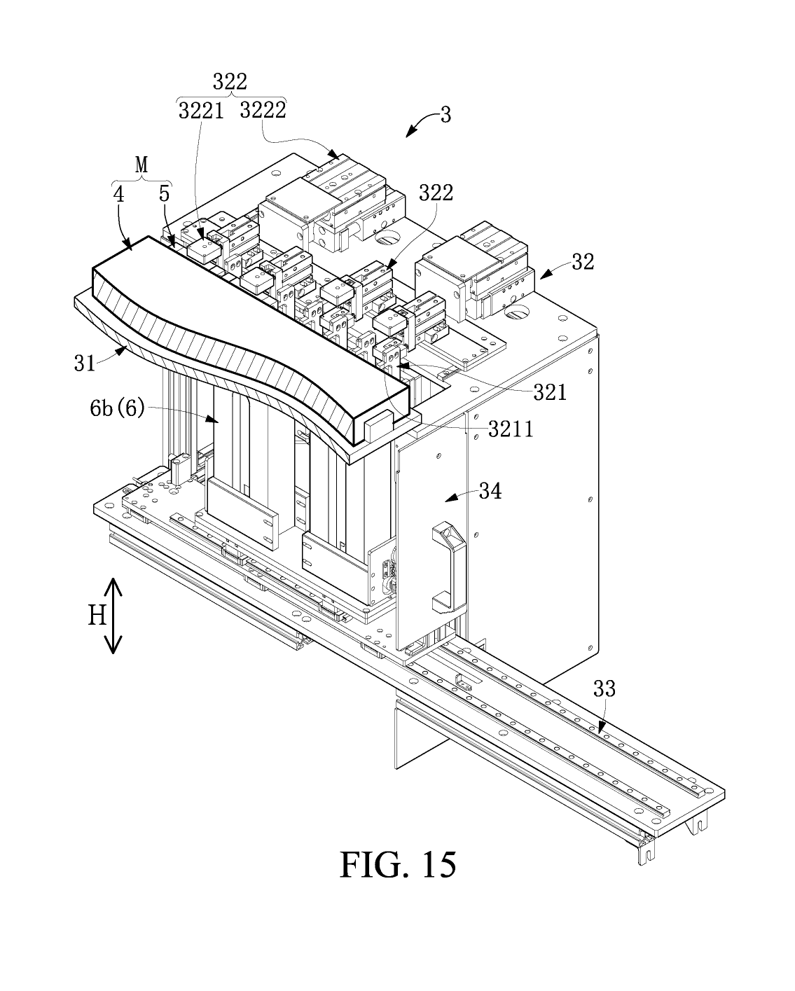

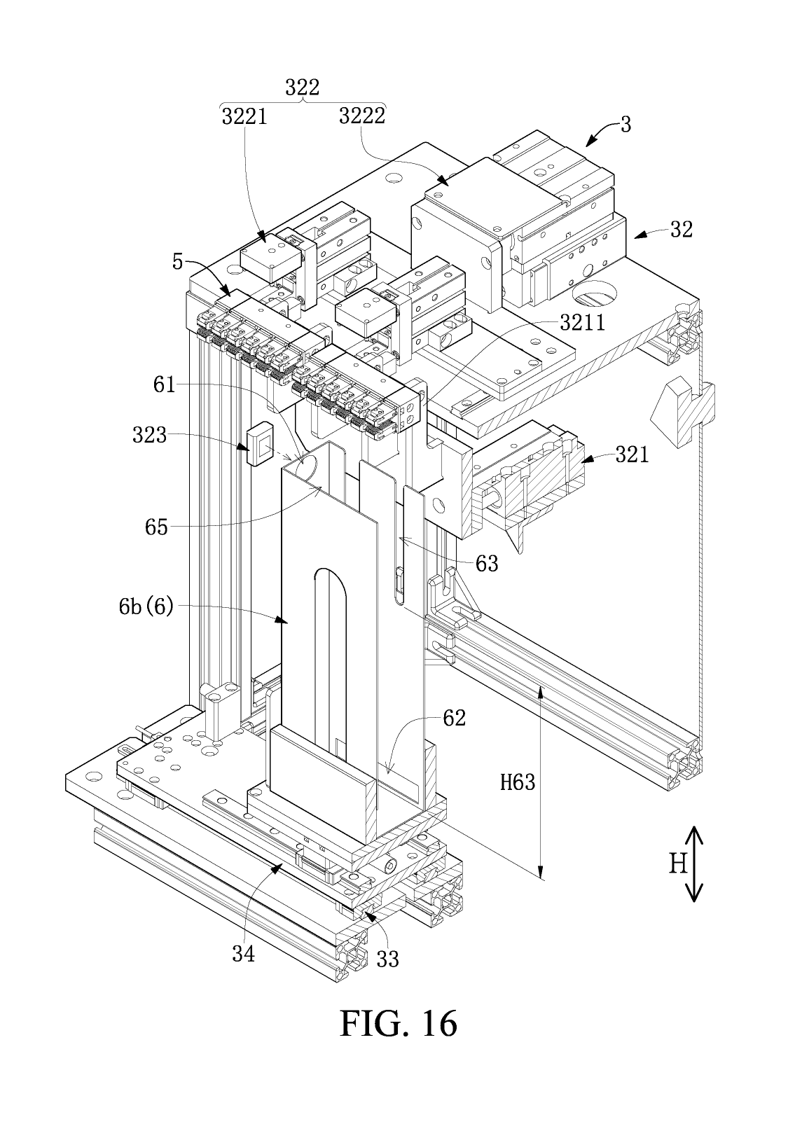

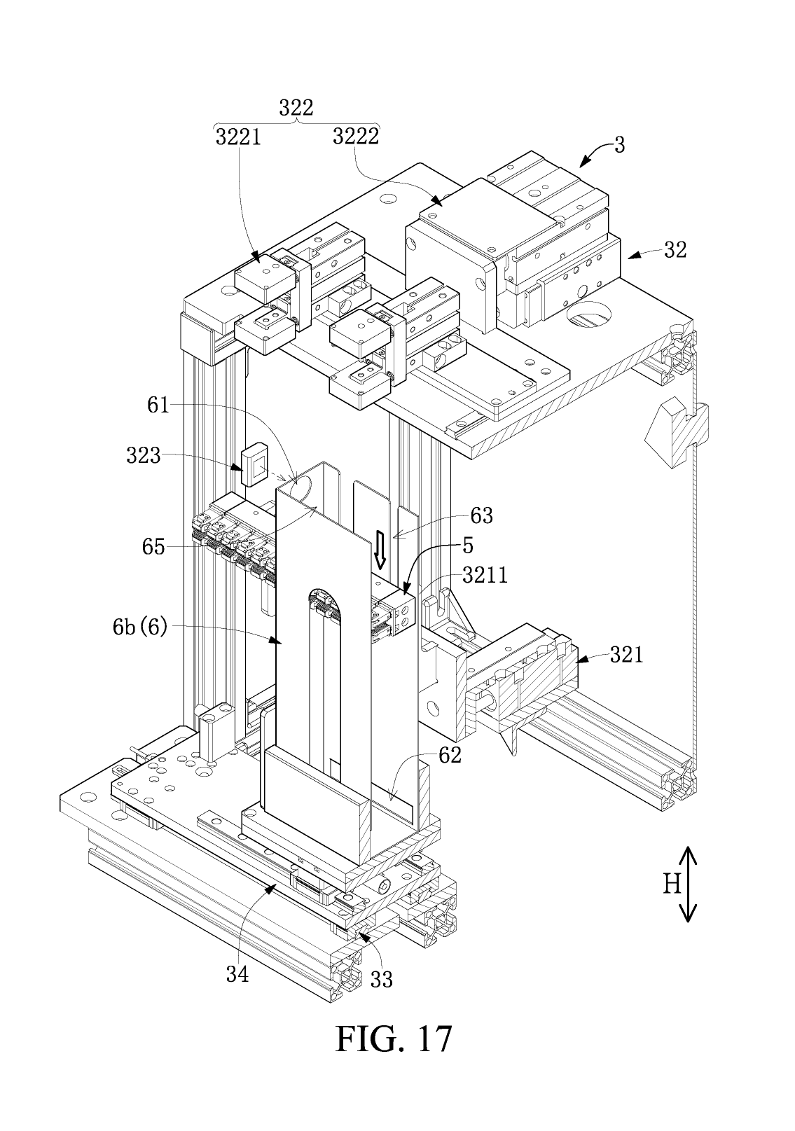

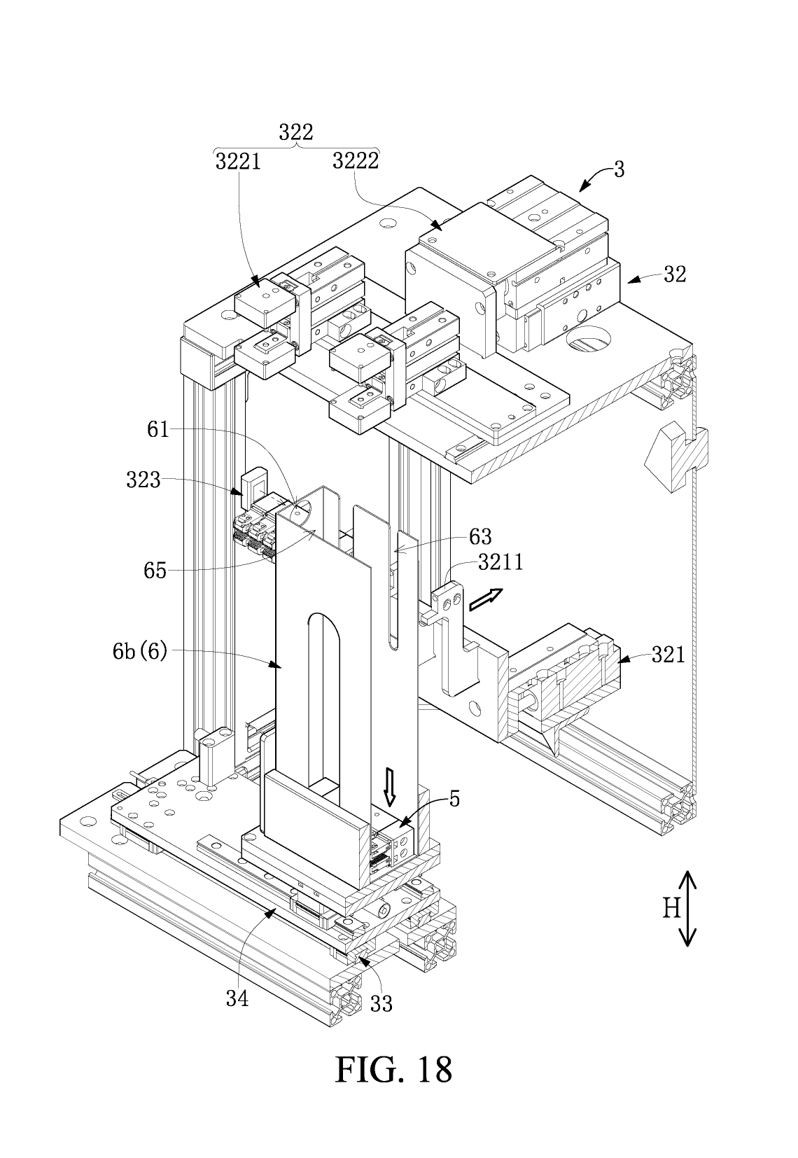

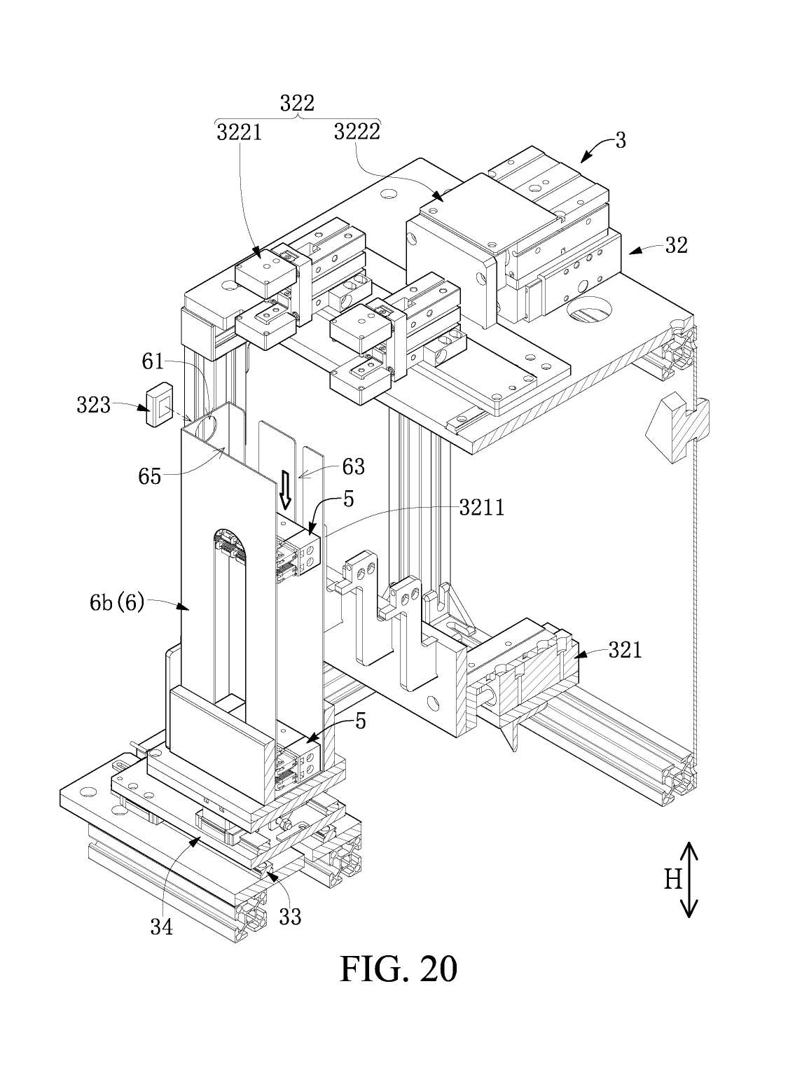

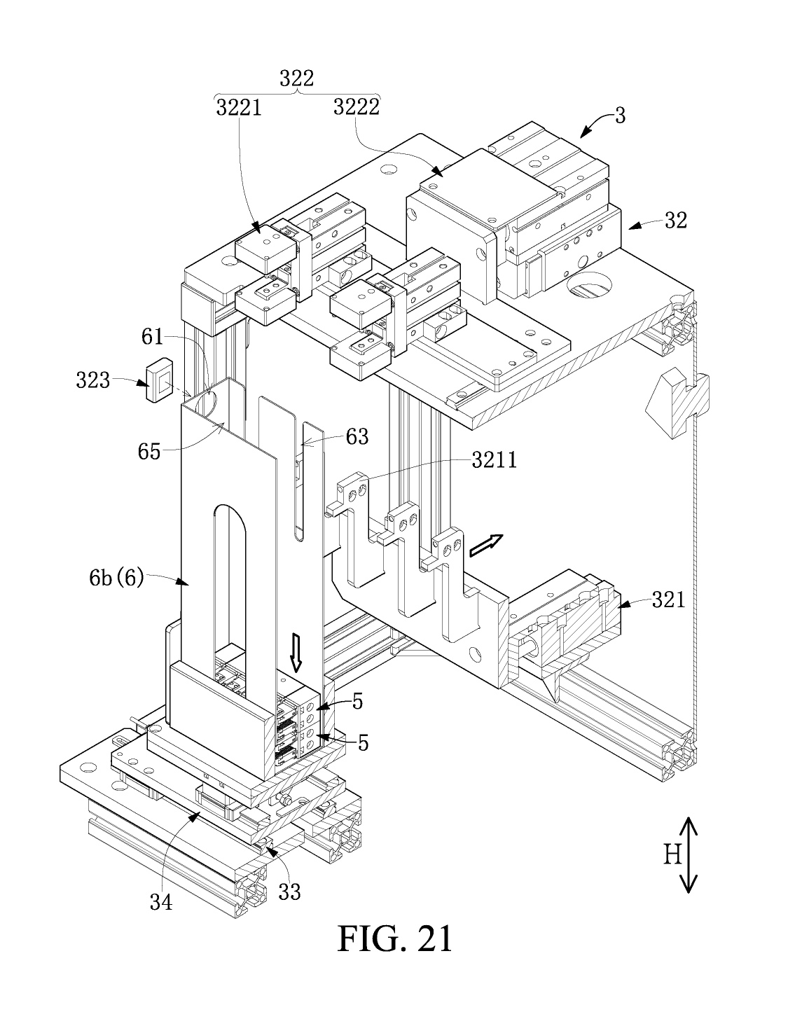

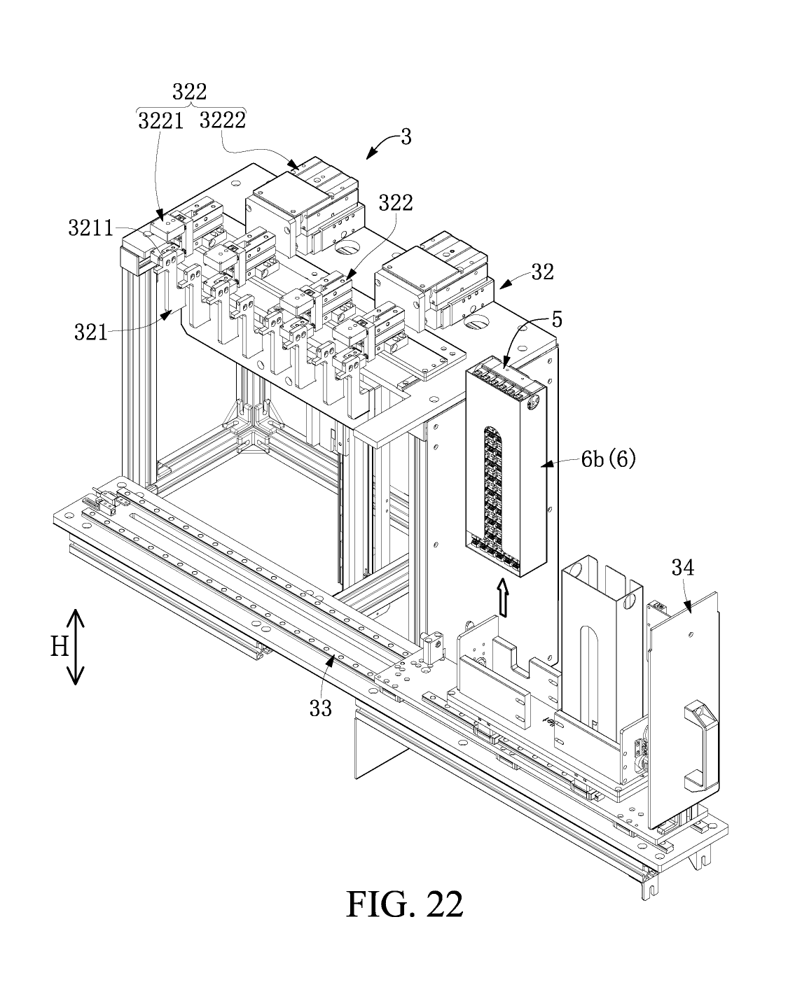

Referring to FIG. 1 to FIG. 22, which illustrate an embodiment of the present disclosure. As shown in FIG. 1, the present embodiment discloses a processing system for an electronic device 100, which includes an insertion apparatus 1, a work station 2 located downstream of the insertion apparatus 1, and a pull-out apparatus 3 located downstream of the work station 2, but the present disclosure is not limited thereto. For example, in other embodiments of the present disclosure not shown in the drawings, the insertion apparatus 1 or the pull-out apparatus 3 may also be applied independently (for example: sold) or used in combination with other components according to practical requirements. The following description will further describe the respective component structures of the processing system for an electronic device 100 in the present embodiment, but is not limited thereto.

### [Insertion Apparatus]

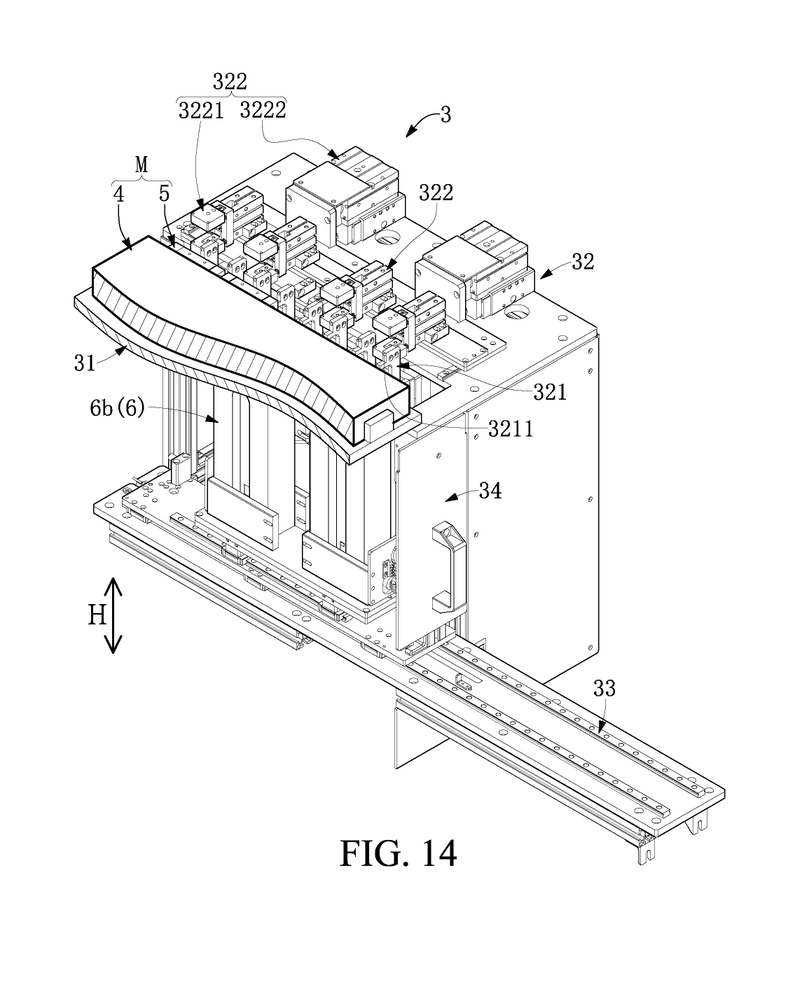

Referring to FIG. 1 to FIG. 13, which disclose the insertion apparatus 1 of the present embodiment. As shown in FIG. 1 to FIG. 4, the insertion apparatus 1 includes a transportation device 11 and an insertion device 12 disposed adjacent to the transportation device 11. In the present embodiment, the transportation device 11 and the insertion device 12 are mounted on an insertion workbench 7. The transportation device 11 is configured to receive an electronic device 4 and position the electronic device 4 to a pending insertion region. Further, the insertion device 12 is configured to insert a connection member 5 into the electronic device 4 located in the pending insertion region, and the electronic device 4 together with the connection member 5 plugged thereon jointly define an electronic module M (for example: FIG. 14).

It should be noted that the drawings of the present embodiment illustrate the electronic module M as being configured with two connection members 5, but for convenience of description, the following description will describe the electronic module M as being configured with one connection member 5 and corresponding structures of the insertion device 12, but the present disclosure is not limited thereto. For example, the electronic device 4 may be plugged with one or three or more connection members 5, and jointly define the electronic module M.

In the present embodiment, the electronic device 4 is described as a server, and the electronic device 4 includes a plurality of ports 41 arranged in two rows and an identification code 42 located on one side of the two rows of the ports 41. Each port 41 is exemplified as a socket connector (for example: RJ45 socket connector), but the present disclosure is not limited thereto.

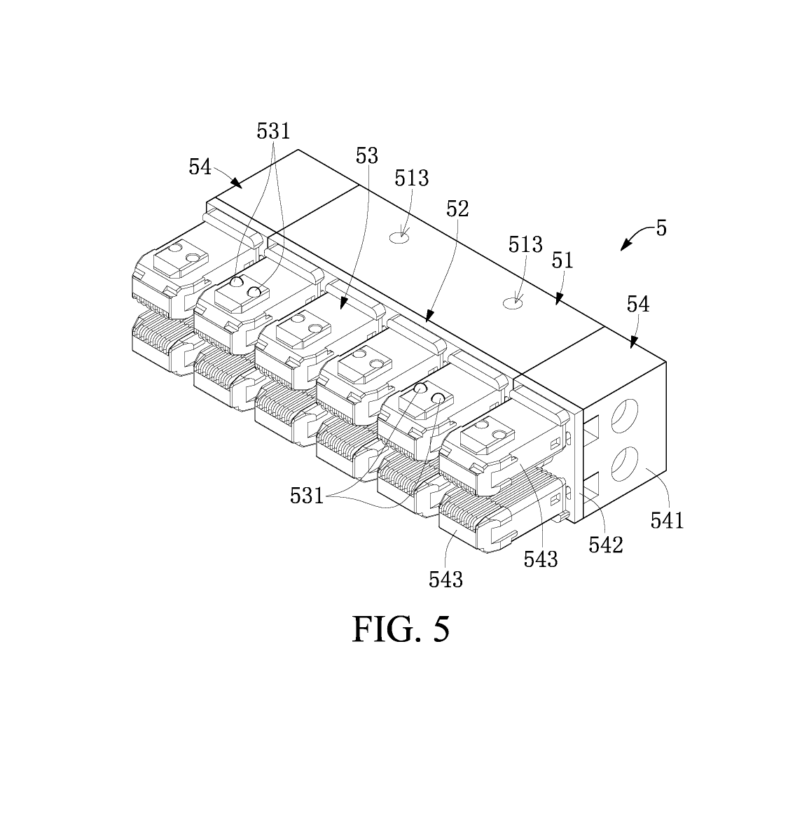

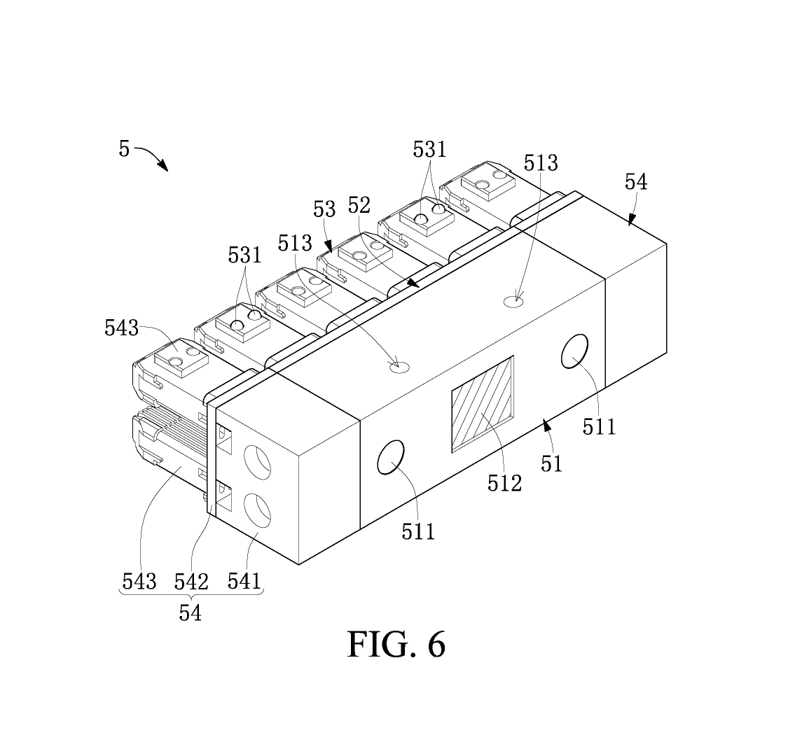

Further, as shown in FIG. 5, FIG. 6, and FIG. 14, the connection member 5 includes a positioning carrier 51, a circuit board 52 disposed at a front end of the positioning carrier 51, and a plurality of connectors 53 disposed on the circuit board 52 (that is, the connectors 53 are located at the front end of the positioning carrier 51). In the present embodiment, the positioning carrier 51 is in the form of a rectangular block, and a magnetically attractable portion 511 and a recognition code 512 are disposed at its rear end. The magnetically attractable portion 511 may include two magnets of different polarities that are located on opposite sides of the recognition code 512, and a plurality of positioning holes 513 are further formed at a top end and a bottom end of the positioning carrier 51, but the present disclosure is not limited thereto.

The connectors 53 of the connection member 5 are arranged in two rows, and any one row of the connectors 53 is electrically coupled to the other row of the connectors 53 through the circuit board 52. In the present embodiment, each of the connectors 53 is exemplified as a plug connector (for example: a RJ45 plug connector) corresponding to the port 41, and the connectors 53 of the connection member 5 are configured to be respectively inserted into the ports 41 of the electronic device 4. Further, in each row of the connectors 53, at least two connectors 53 are respectively provided with a positioning ball 531 configured to engage an inner wall of the corresponding port 41, thereby improving the coupling strength of the connection between the connection member 5 and the electronic device 4.

As described above, the connection member 5 can, through the cooperation of the connectors 53 and the circuit board 52, effectively replace multiple cables adopted by the prior art, thereby facilitating application in automated operations. Further, the connection member 5 is further provided with the magnetically attractable portion 511 for positioning the connection member 5, which further facilitates the connection member 5 to be applied in automated operations.

It should be noted that a quantity of the ports 41 may vary depending on the model of the electronic device 4, and therefore the connection member 5 may further include at least one expansion unit 54 mounted to the positioning carrier 51. In the present embodiment, a quantity of the at least one expansion unit 54 is described as two. The two expansion units 54 are respectively mounted to two side ends of the positioning carrier 51, and the structures of the two expansion units 54 are substantially the same or mirror-symmetric, but the present disclosure is not limited thereto. For example, in other embodiments of the present disclosure not shown in the drawings, the two expansion units 54 may be slightly different from each other according to design requirements; or the connection member 5 may adopt at least one expansion unit 54 or may not use the expansion unit 54 depending on the model of the electronic device 4.

Moreover, each of the two expansion units 54 includes an expansion carrier 541, an expansion circuit board 542 disposed at a front end of the expansion carrier 541, and two expansion connectors 543 disposed on the expansion circuit board 542 (that is, the two expansion connectors 543 are located at the front end of the expansion carrier 541). Any one of the expansion connectors 543 is electrically coupled to the other expansion connector 543 through the expansion circuit board 542.

Further, the expansion carriers 541 of the two expansion units 54 are respectively mounted (for example: fastened) to the two side ends of the positioning carrier 51; that is, each of the expansion carriers 541 is detachably mounted to one of the two side ends of the positioning carrier 51. Moreover, the two expansion connectors 543 of each of the expansion units 54 are respectively disposed along the two rows of the connectors 53. Accordingly, the connectors 53 and the expansion connectors 543 of the connection member 5 are configured to be respectively inserted into the ports 41 of the electronic device 4.

The above contents describe the respective structures of the electronic device 4 and the connection member 5 and their corresponding relationship. The following description will introduce the configuration of the insertion apparatus 1 used with the electronic device 4 and the connection member 5 to implement an automated plugging process between the electronic device 4 and the connection member 5.

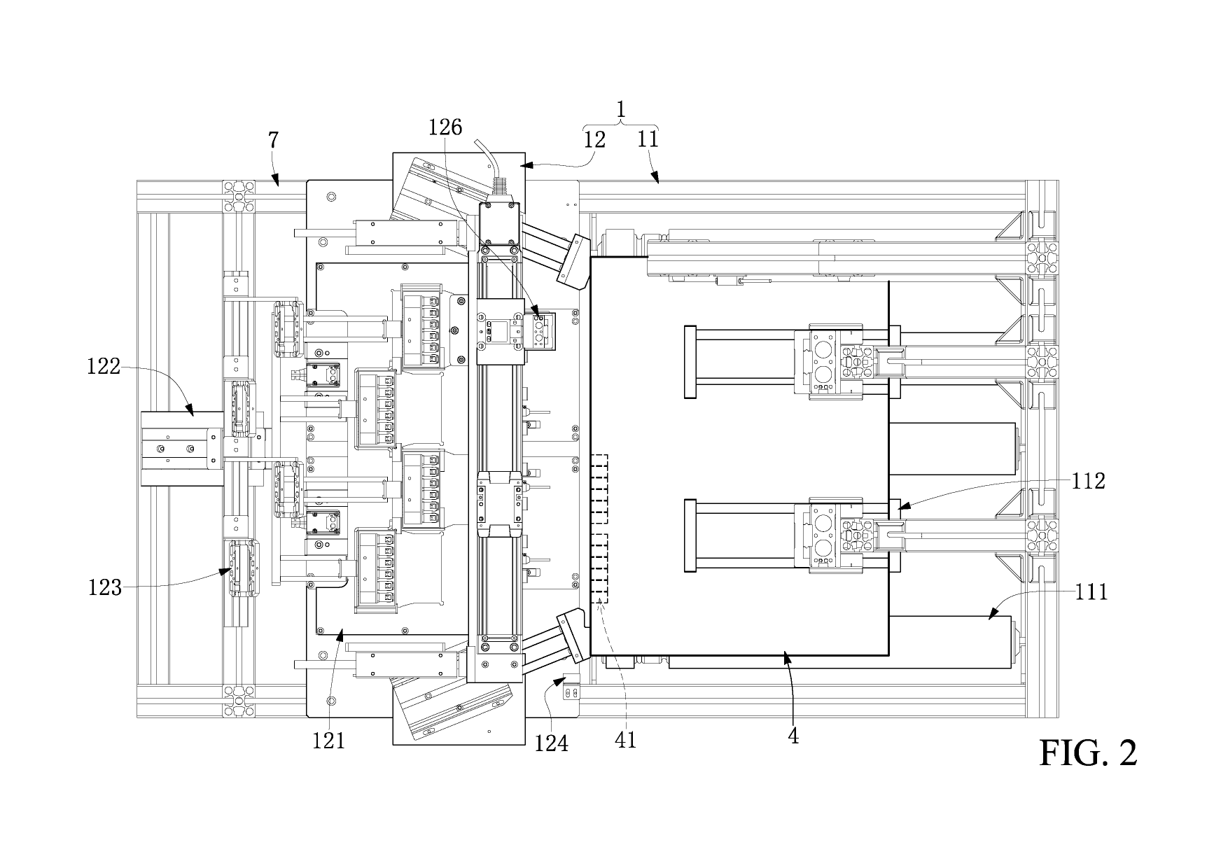

As shown in FIG. 2 to FIG. 5, the transportation device 11 includes a transportation track 111 (for example: a plurality of rollers or a conveyor belt) and a positioning mechanism 112 (for example: a plurality of pushing arms) arranged corresponding to the transportation track 111. The transportation track 111 can be used to receive the electronic device 4, and the positioning mechanism 112 is used to push the electronic device 4 located on the transportation track 111 toward the insertion device 12 and position it at the pending insertion region. The transportation track 111 can also be used to transport the electronic device 4 in which the connection member 5 is inserted (that is, the electronic module M) toward the work station 2.

The insertion device 12 includes a support frame 121, a supply cassette 6a disposed on the support frame 121, an ejecting mechanism 122 disposed corresponding to the supply cassette 6a, a reader 123 facing the supply cassette 6a, an identification mechanism 124 facing the pending insertion region, a pushing-in mechanism 125 located below the support frame 121, and a transfer mechanism 126, but the present disclosure is not limited thereto. For example, in other embodiments of the present disclosure not shown in the drawings, the support frame 121 may also be omitted or replaced with other components according to design requirements.

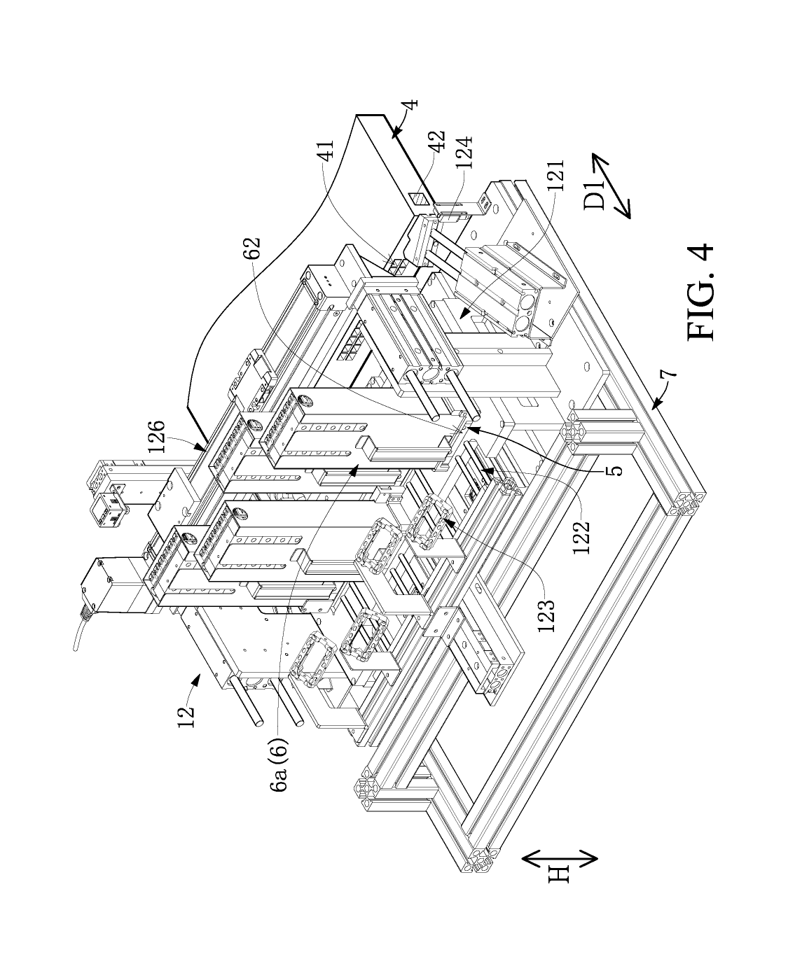

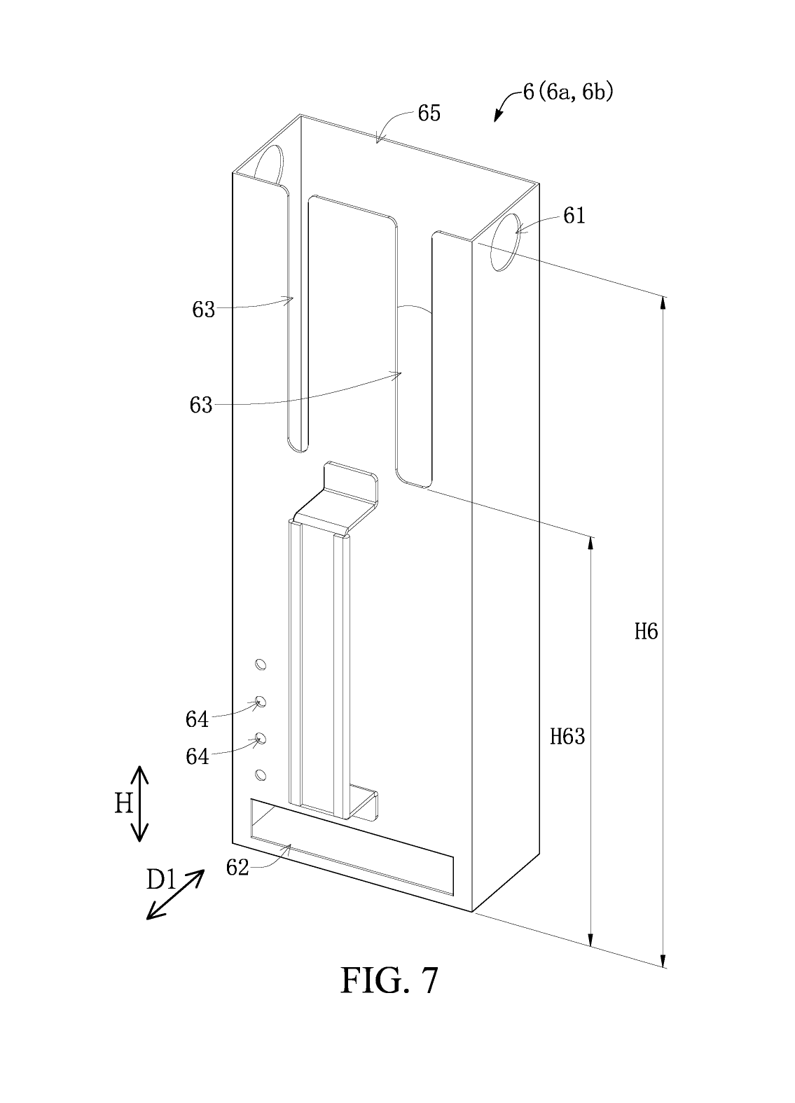

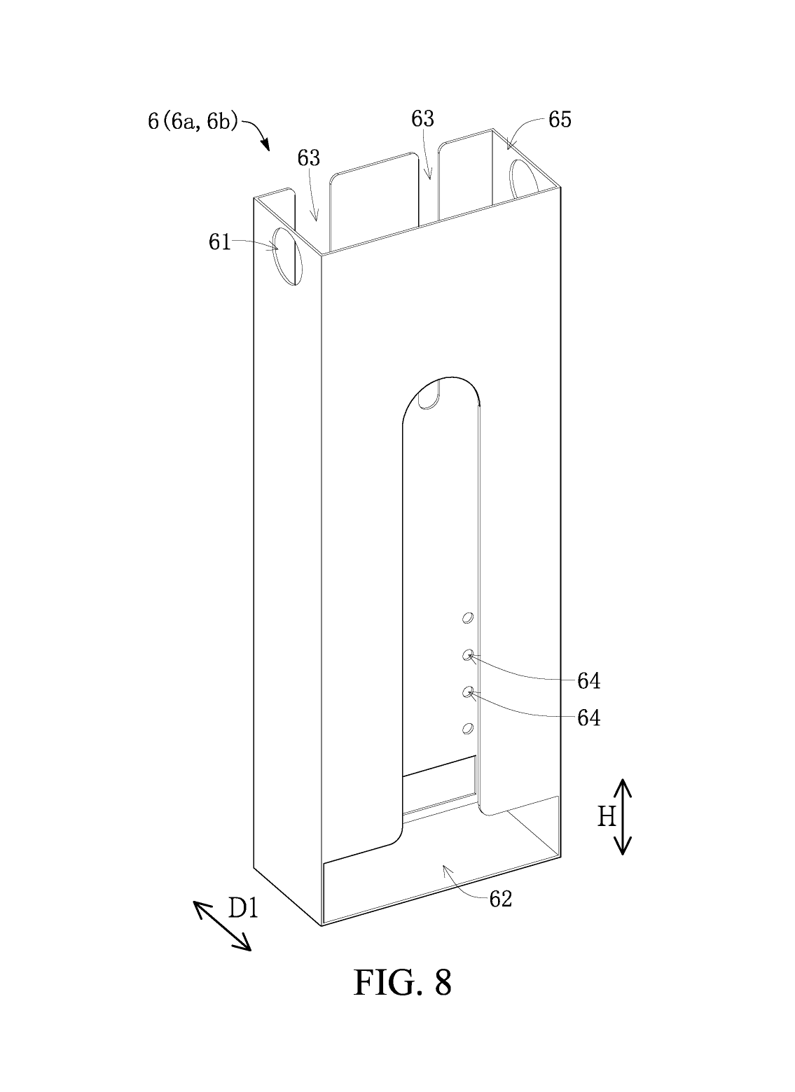

It should be noted that, as shown in FIG. 4, FIG. 7, and FIG. 8, the supply cassette 6a may also be referred to as a cassette 6, which is configured to accommodate a plurality of connection members 5 stacked therein along a height direction H. In the present embodiment, the cassette 6 is made of a sheet metal structure and adopts a magazine-style filling of the connection members 5, thereby achieving both low cost and high performance.

More specifically, the cassette 6 includes a full-level detection hole 61 located at its top, a discharge slot 62 located at its bottom, a rail groove 63, and a plurality of inventory display holes 64 located between the discharge slot 62 and the rail groove 63. When the connection members 5 fill the inside of the cassette 6, the uppermost connection member 5 can be seen from the full-level detection hole 61 of the cassette 6, and the position of each of the inventory display holes 64 corresponds to one of the connection members 5. Therefore, the corresponding connection member 5 at each position can be seen through each of the inventory display holes 64 of the cassette 6, thereby facilitating the real-time knowledge of the number of the connection members 5 inside the cassette 6.

Further, the discharge slot 62 extends (e.g., is formed by penetrating) through the cassette 6 in a first direction D1 perpendicular to the height direction H, and the discharge slot 62 is configured to allow one of the connection members 5 to be disposed therein; that is, the configuration of the discharge slot 62 can allow the connection member 5 located therein to be pushed out of the cassette 6. The rail groove 63 is formed by being recessed from a mouth 65 of the cassette 6 toward the discharge slot 62, and in the present embodiment the rail groove 63 is described as two sub-rails parallel to the height direction H. There is a drop depth H63 between a bottom edge of the cassette 6 and a bottom edge of the rail groove 63, and the drop depth H63 is within a range from 35% to 40% of a length H6 of the cassette 6 in the height direction H, but the present disclosure is not limited thereto.

As described above, in the present embodiment the cassette 6 can, through the above structural design, provide a configuration of filling from above and supplying from below, thereby realizing a magazine-style loading for the connection members 5, which is suitable for application in automated operations.

It should be noted that although the cassette 6 is introduced with the above structure, its specific structure can be adjusted and varied according to design requirements. For example, in other embodiments of the present disclosure not shown in the drawings, when the cassette 6 is only used in the insertion device 12 (that is, the cassette 6 is only used as the supply cassette 6a), at least one of the rail groove 63, the full-level detection hole 61, and the inventory display holes 64 may be omitted.

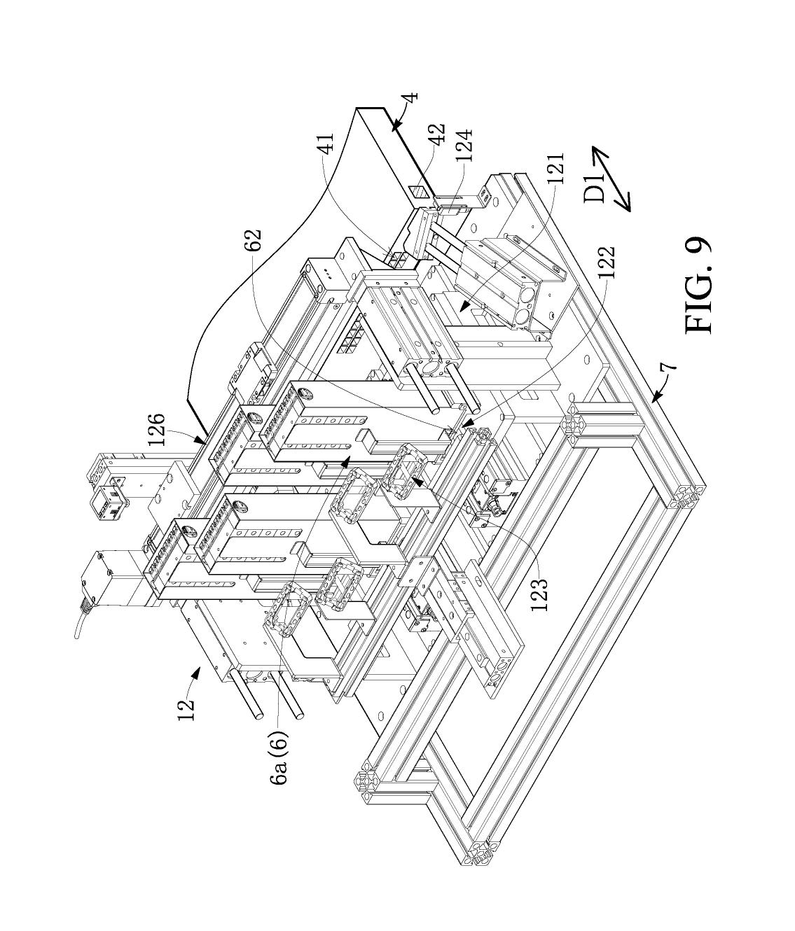

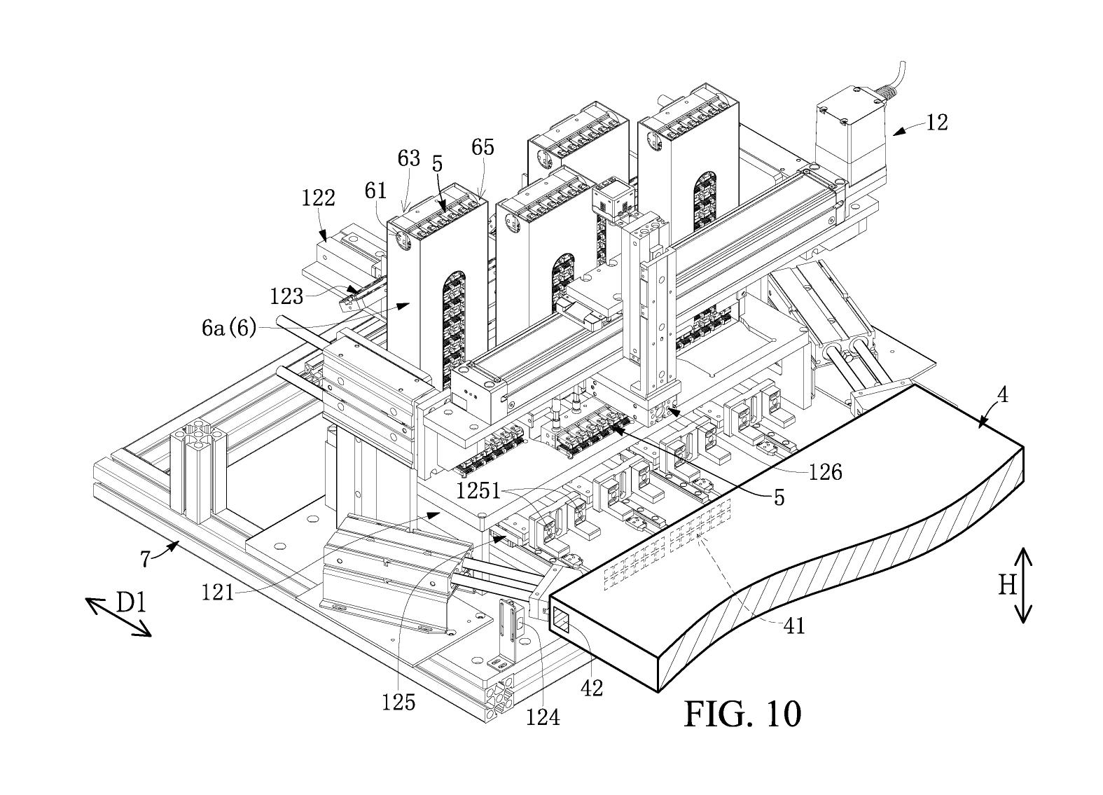

As shown in FIG. 2 to FIG. 4, and FIG. 9 and FIG. 10 (refer to FIG. 5 and FIG. 6 for the structure of the connection member 5, and refer to FIG. 7 and FIG. 8 for the structure of the cassette 6), the ejecting mechanism 122 is disposed corresponding to the discharge slot 62, and the ejecting mechanism 122 is configured to push out the connection member 5 disposed in the discharge slot 62 to be located at a pending pick-up position (for example: FIG. 10). Further, when the ejecting mechanism 122 pushes the connection member 5 disposed in the discharge slot 62 along the first direction D1, another connection member 5 (or the remaining connection members 5) in the supply cassette 6a falls into the discharge slot 62 through gravity.

The ejecting mechanism 122 is implemented as a cylinder, the reader 123 is adjacent to the ejecting mechanism 122 and is configured to scan the recognition code 512 of the connection member 5 disposed in the discharge slot 62, and the identification mechanism 124 is configured to read an identification code 42 of the electronic device 4. Moreover, when the recognition code 512 corresponds to the identification code 42 in the insertion device 12, the ejecting mechanism 122 is driven to push out the connection member 5 disposed in the discharge slot 62 to be located at the pending pick-up position.

Accordingly, the insertion device 12 can, through the configuration of the reader 123 and the identification mechanism 124, effectively ensure that the connection member 5 pushed out by the ejecting mechanism 122 is compatible with the electronic device 4.

As shown in FIG. 10 to FIG. 13 (refer to FIG. 5 and FIG. 6 for the structure of the connection member 5, and refer to FIG. 7 and FIG. 8 for the structure of the cassette 6), the pushing-in mechanism 125 is disposed adjacent to the pending insertion region and has a magnetically attractive end 1251 facing the pending insertion region. Furthermore, the pushing-in mechanism 125 is, for example, an electric cylinder, and its magnetically attractive end 1251 protrudes from the support frame 121 so that the transfer mechanism 126 can move the connection member 5 located at the pending pick-up position to the pushing-in mechanism 125 and be attracted and fixed by the magnetically attractive end 1251 through the magnetically attractable portion 511. In addition, the pushing-in mechanism 125 is configured to push the connection member 5 attracted thereby toward the pending insertion region to cause the connectors 53 to be respectively inserted into the ports 41, thereby jointly constituting the electronic module M.

It should be noted that the transfer mechanism 126 adopts a vacuum picker to attract and transport the connection member 5. The magnetically attractive end 1251 includes two magnets with polarities respectively opposite to the two magnets of the magnetically attractable portion 511, so that the connection member 5 can be accurately and stably positioned on the pushing-in mechanism 125 through magnetic attraction between the magnetically attractable portion 511 and the magnetically attractive end 1251.

As described above, the insertion apparatus 1 can realize automated plugging between the electronic device 4 and the connection member 5 through the coordinated arrangement of its components, thereby reducing labor and effectively improving overall operational efficiency.

### [Work Station]

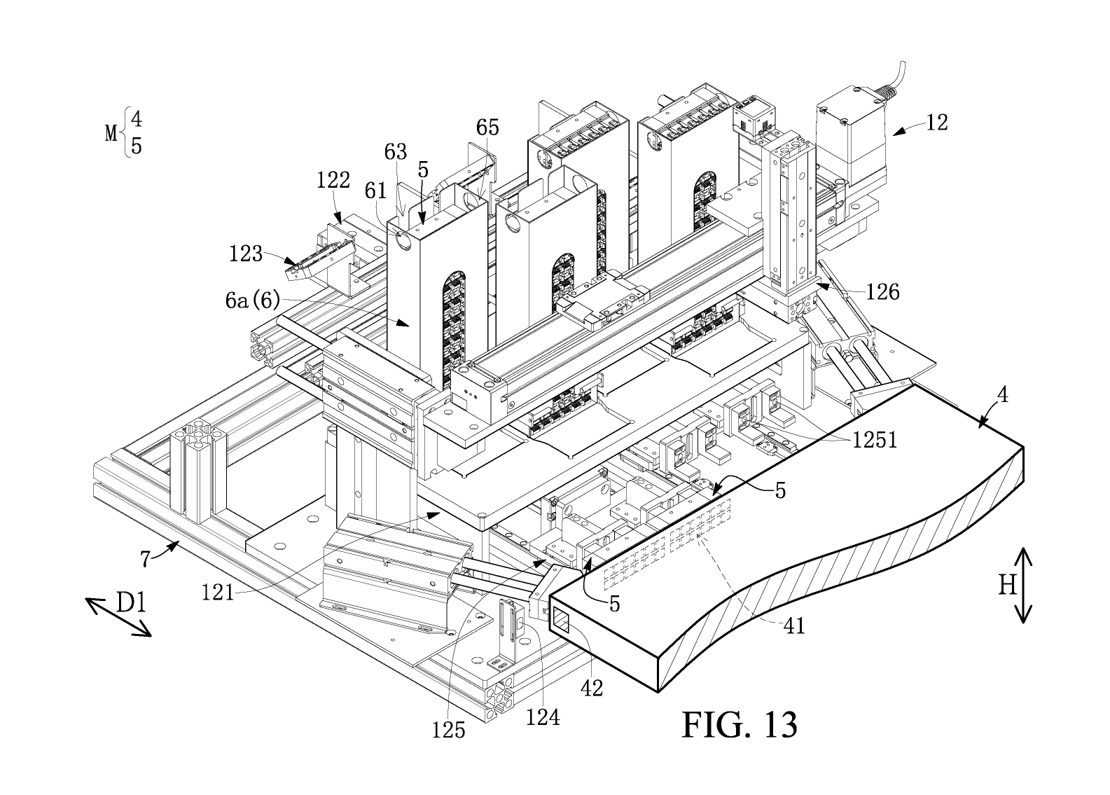

As shown in FIG. 1 and FIG. 13, the work station 2 is configured to receive the electronic module M and perform a predetermined operation on the electronic module M. The predetermined operation can be adjusted and varied according to actual requirements, and the present disclosure is not limited thereto. For example, the predetermined operation may be an electrical inspection operation of the electronic module M. It should be noted that the work station 2 is preferably configured to obtain the electronic module M from the insertion apparatus 1 by mechanical means (for example: a conveyor belt or a robotic arm), but the present disclosure is not limited thereto.

### [Pull-Out Apparatus]

Referring to FIG. 1 and FIG. 14 to FIG. 22 (refer to FIG. 5 and FIG. 6 for the structure of the connection member 5, and refer to FIG. 7 and FIG. 8 for the structure of the cassette 6), which disclose the pull-out apparatus 3 of the present embodiment. The pull-out apparatus 3 includes a carrying platform 31, a pull-out device 32 disposed adjacent to the carrying platform 31, a rail 33 located below a junction between the carrying platform 31 and the pull-out device 32, and a drawer 34 mounted to the rail 33. In the present embodiment, the carrying platform 31, the pull-out device 32, the rail 33, and the drawer 34 are mounted on a pull-out workbench (not shown in the drawings), but the present disclosure is not limited thereto. For example, in other embodiments of the present disclosure not shown in the drawings, the rail 33 and the drawer 34 may also be omitted or replaced with other components according to practical requirements.

The carrying platform 31 is configured to receive and position the electronic module M after completion of the predetermined operation, and the pull-out device 32 can be used to pull the connection member 5 of the electronic module M out of the electronic device 4. The carrying platform 31 is preferably configured to obtain the electronic module M that has completed the predetermined operation from the work station 2 by mechanical means (for example: a conveyor belt or a robotic arm), but the present disclosure is not limited thereto.

The pull-out device 32 includes a placement mechanism 321, a receiving cassette 6b disposed corresponding to the placement mechanism 321, a pulling mechanism 322 cooperating with the placement mechanism 321, and a receiving detector 323 facing the receiving cassette 6b. It should be noted that in the following description, the placement mechanism 321, the receiving cassette 6b, the pulling mechanism 322, and the receiving detector 323 are each described as a single unit, but the present disclosure is not limited thereto.

Further, the structure of the receiving cassette 6b is identical to that of the supply cassette 6a, and therefore the receiving cassette 6b may also be referred to as the cassette 6, but the present disclosure is not limited thereto. For example, in other embodiments of the present disclosure not shown in the drawings, when the cassette 6 is only used in the pull-out device 32 (that is, the cassette 6 is only used as the receiving cassette 6b), at least one of the discharge slot 62, the full-level detection hole 61, and the inventory display holes 64 may be omitted.

The placement mechanism 321 includes a magnetic seat 3211 facing the carrying platform 31 and a displacement unit (not shown in the drawings) connected to the magnetic seat 3211. The receiving cassette 6b is detachably mounted in the drawer 34 and located below the magnetic seat 3211, and the magnetic seat 3211 is movable (through the displacement unit) along the receiving cassette 6b.

The pulling mechanism 322 includes a gripper 3221 adjacent to the magnetic seat 3211 and a driving cylinder 3222 connected to the gripper 3221. The driving cylinder 3222 can drive the gripper 3221 to move. The pulling mechanism 322 is configured to hold the connection member 5 of the electronic device 4 with the gripper 3221 (for example: the gripper 3221 can hold the connection member 5 by being inserted into the positioning holes 513 of the connection member 5), and the pulling mechanism 322 is configured to move the gripper 3221 toward the magnetic seat 3211, so that the connection member 5 is separated from the electronic device 4 and attracted and positioned on the magnetic seat 3211 by the magnetically attractable portion 511.

Accordingly, the pull-out apparatus 3 can realize automated removal of the connection member 5 from the electronic device 4 through the coordinated arrangement of its components, thereby reducing labor and effectively improving overall operational efficiency.

As described above, the processing system for the electronic device 100 can, by the respective structural configurations of the insertion apparatus 1 and the pull-out apparatus 3, be positioned upstream and downstream of the work station 2, respectively, thereby enabling the predetermined operation of the electronic device 4 to be performed through automatic plugging and unplugging of the connection member 5, thereby reducing labor and effectively improving overall operational efficiency.

It should be noted that the magnetic seat 3211 includes two magnets with polarities respectively opposite to the two magnets of the magnetically attractable portion 511, so that the connection member 5 can be accurately and stably positioned on the pulling mechanism 322 through magnetic attraction between the magnetically attractable portion 511 and the magnetic seat 3211.

Further, the magnetic seat 3211 is configured to move the connection member 5 attracted thereby toward the receiving cassette 6b so that the connection member 5 is placed into the receiving cassette 6b. Moreover, the magnetic seat 3211 is movable along the rail groove 63 of the receiving cassette 6b to move the connection member 5 attracted thereby into the mouth 65 of the receiving cassette 6b, and then the magnetic seat 3211 moves away from the rail groove 63 so that the connection member 5 disengages from the magnetic seat 3211 and falls into the receiving cassette 6b. In the present embodiment, the receiving cassette 6b ensures that the connection member 5 falling through gravity does not cause damage by restricting the drop depth H63 within a certain range.

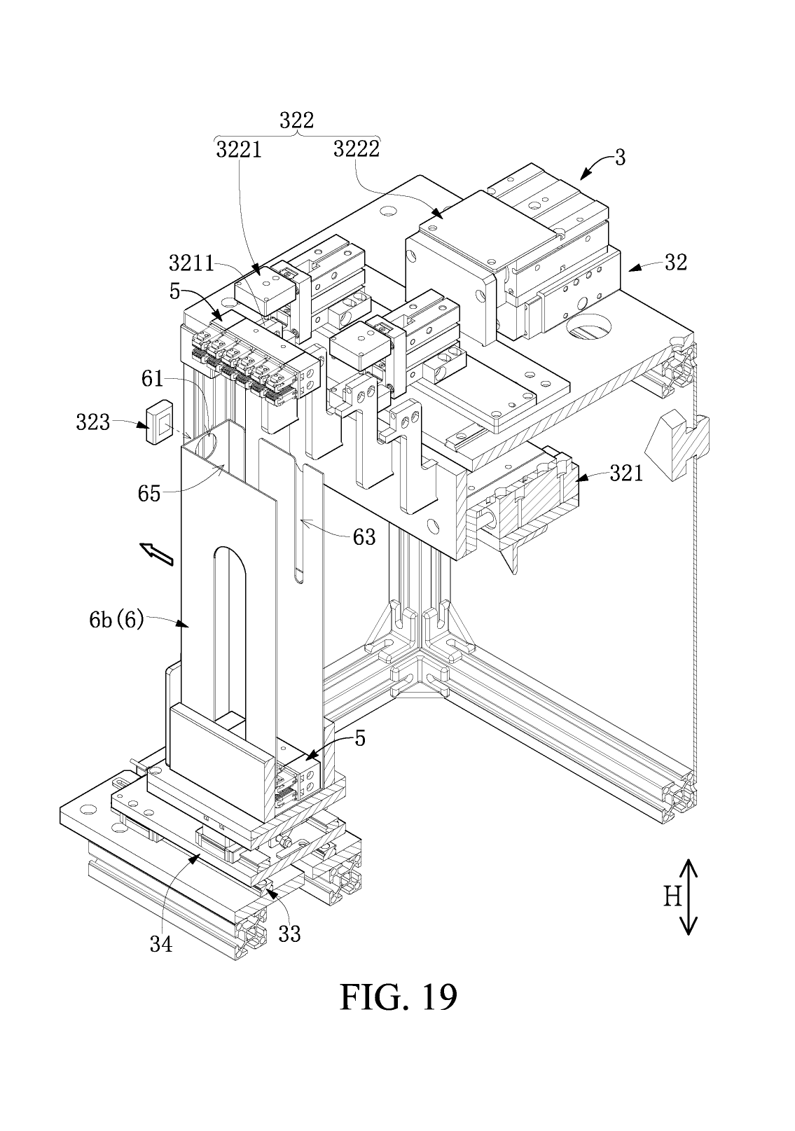

It should be noted that when the electronic device 4 of the electronic module M is inserted with two connection members 5 adjacent to each other, the receiving cassette 6b can, after accommodating one of the connection members 5, move below the other connection member 5 through the drawer 34 and the rail 33 so as to accommodate the other connection member 5 (for example: FIG. 19).

The receiving detector 323 faces the full-level detection hole 61 of the receiving cassette 6b so that when the receiving detector 323 detects, through the full-level detection hole 61, that the receiving cassette 6b contains the connection member 5 at a position adjacent to the full-level detection hole 61, the pull-out device 32 stops operating. In addition, the drawer 34 of the pull-out device 32 is movable along the rail 33 such that the receiving cassette 6b leaves a position below the magnetic seat 3211 so a receiving cassette 6b not containing the connection member 5 can be mounted.

Since in the present embodiment the receiving cassette 6b and the supply cassette 6a adopt the same structure, they can be used in conjunction with the connection members 5 to achieve a recycling effect. Specifically, when the receiving cassette 6b is already filled (e.g., fully filled) with the connection members 5, the receiving cassette 6b can be detached from the pull-out device 32 and mounted to the insertion device 12 for use as the supply cassette 6a. Alternatively, when the supply cassette 6a is empty of the connection members 5, the supply cassette 6a can be detached from the insertion device 12 and mounted to the pull-out device 32 for use as the receiving cassette 6b.

### [Technical Effects of Embodiments]

In view of the above, the processing system for an electronic device of the present disclosure can, by the respective structural configurations of the insertion apparatus and the pull-out apparatus, be respectively disposed upstream and downstream of the work station, thereby enabling the predetermined operation of the electronic device to be performed through automatic plugging and unplugging of the connection member, thereby reducing labor and effectively improving overall operational efficiency.

Further, the insertion apparatus and the pull-out apparatus of the present disclosure can realize automated plugging and unplugging of the connection member to the electronic device through the coordinated arrangement of components, thereby reducing labor and effectively improving overall operational efficiency.

Moreover, the connection member of the present disclosure can, through the cooperation of the connectors and the circuit board, effectively replace multiple cables adopted by the prior art, facilitating application in automated operations. The connection member is further provided with the magnetically attractable portion for positioning the connection member, which further facilitates the connection member to be applied in automated operations.

In addition, the cassette of the present disclosure can, through structural design, provide a configuration of filling from above and supplying from below, thereby realizing a magazine-style filling function for the connection members, which is suitable for application in automated operations.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An insertion apparatus, comprising:
a transportation device configured to receive an electronic device and position the electronic device to a pending insertion region; wherein the electronic device comprises a plurality of ports; and
an insertion device disposed adjacent to the transportation device, the insertion device comprising:
a supply cassette configured to accommodate a plurality of connection members stacked therein, and comprising a discharge slot that is formed at a bottom of the supply cassette and that is configured to allow one of the plurality of connection members to be disposed therein; wherein each of the plurality of connection members comprises a plurality of connectors at a front end thereof and a magnetically attractable portion at a rear end thereof;
an ejecting mechanism disposed corresponding to the discharge slot, the ejecting mechanism being configured to push out the connection member disposed in the discharge slot to be located at a pending pick-up position;
a pushing-in mechanism disposed adjacent to the pending insertion region and having a magnetically attractive end facing the pending insertion region; and
a transfer mechanism configured to move the connection member located at the pending pick-up position to the pushing-in mechanism so that the connection member is attracted and fixed by the magnetically attractive end through the magnetically attractable portion;
wherein the pushing-in mechanism is configured to push the connection member attracted thereby toward the pending insertion region so that the plurality of connectors are respectively inserted into the plurality of ports.

2. The insertion apparatus according to claim 1, wherein the insertion device comprises a support frame, the supply cassette is disposed on the support frame, the pushing-in mechanism is located below the support frame, and the magnetically attractive end protrudes from the support frame.

3. The insertion apparatus according to claim 1, wherein the supply cassette is configured to accommodate the plurality of connection members stacked therein along a height direction, and the discharge slot is formed by penetrating through the supply cassette in a first direction perpendicular to the height direction.

4. The insertion apparatus according to claim 3, wherein the ejecting mechanism is configured to push, along the first direction, the connection member disposed in the discharge slot, so that another one of the plurality of connection members in the supply cassette falls by gravity into the discharge slot.

5. The insertion apparatus according to claim 1, wherein each of the plurality of connection members has a recognition code at a rear end thereof; and wherein the insertion device comprises a reader that is arranged adjacent to the ejecting mechanism and that is configured to scan the recognition code of the connection member disposed in the discharge slot.

6. The insertion apparatus according to claim 5, wherein the insertion device has an identification mechanism configured to read an identification code of the electronic device; wherein, when the recognition code corresponds to the identification code in the insertion device, the ejecting mechanism is driven to push out the connection member disposed in the discharge slot to be located at the pending pick-up position.

7. A pull-out apparatus, comprising:
a carrying platform configured to receive and position an electronic device and a connection member inserted into the electronic device; wherein the connection member comprises a magnetically attractable portion at a rear end thereof; and
a pull-out device disposed adjacent to the carrying platform, the pull-out device comprising:
a placement mechanism comprising a magnetic seat facing the carrying platform;
a receiving cassette disposed below the magnetic seat, the magnetic seat being movable along the receiving cassette; and
a pulling mechanism comprising a gripper adjacent to the magnetic seat; wherein the pulling mechanism is configured to hold the connection member of the electronic device through the gripper and to move the gripper toward the magnetic seat, so that the connection member is separated from the electronic device and is attracted and positioned on the magnetic seat through the magnetically attractable portion;
wherein the magnetic seat is configured to move the connection member attracted thereby toward the receiving cassette so that the connection member is placed into the receiving cassette.

8. The pull-out apparatus according to claim 7, further comprising a rail and a drawer mounted to the rail, wherein the receiving cassette is detachably mounted within the drawer; and wherein the drawer is movable along the rail such that the receiving cassette leaves a position below the magnetic seat.

9. The pull-out apparatus according to claim 7, wherein the receiving cassette has a rail groove that is recessed from a mouth thereof, and the magnetic seat is movable along the rail groove of the receiving cassette to move the connection member attracted thereby into the mouth of the receiving cassette, and wherein, when the magnetic seat moves away from the rail groove, the connection member disengages from the magnetic seat and falls into the receiving cassette.

10. The pull-out apparatus according to claim 9, wherein a bottom edge of the receiving cassette is spaced apart from a bottom edge of the rail groove by a drop depth that is within a range from 35% to 40% of a length of the receiving cassette in the height direction.

11. The pull-out apparatus according to claim 7, wherein a top of the receiving cassette has a full-level detection hole, and the pull-out device comprises a receiving detector facing the full-level detection hole; and wherein, when the receiving detector detects through the full-level detection hole that the receiving cassette contains the connection member adjacent to the full-level detection hole, the pull-out device stops operating.

12. A connection member, comprising:
a positioning carrier having a magnetically attractable portion disposed at a rear end thereof;
a circuit board disposed at a front end of the positioning carrier; and
a plurality of connectors disposed on the circuit board and arranged in two rows, any one of the two rows of the plurality of connectors being electrically coupled to another one of the two rows of the plurality of connectors through the circuit board;
wherein the plurality of connectors of the connection member are configured to be respectively inserted into a plurality of ports of an electronic device.

13. The connection member according to claim 12, further comprising at least one expansion unit that comprises:
an expansion carrier detachably mounted to one of two side ends of the positioning carrier;
an expansion circuit board disposed at a front end of the expansion carrier; and
two expansion connectors disposed on the expansion circuit board, the two expansion connectors being respectively disposed along the two rows of the plurality of connectors; wherein any one of the two expansion connectors is electrically coupled to another one of the two expansion connectors through the expansion circuit board.

14. The connection member according to claim 12, wherein, in each of the two rows of the plurality of connectors, at least two of the plurality of connectors are respectively provided with a positioning ball configured to engage an inner wall of the corresponding port.

15. The connection member according to claim 12, wherein the positioning carrier has a plurality of positioning holes that are formed at a top end thereof and a bottom end thereof.

16. A processing system for an electronic device, comprising:
an insertion apparatus as described in claim 1, wherein the electronic device together with the connection member plugged thereon jointly define an electronic module;
a work station located at a downstream of the insertion apparatus; wherein the work station is configured to receive the electronic module and perform a predetermined operation on the electronic module; and
a pull-out apparatus located at a downstream of the work station, the pull-out apparatus comprising:
a carrying platform configured to receive and position the electronic module after completion of the predetermined operation; and
a pull-out device disposed adjacent to the carrying platform, the pull-out device comprising:
a placement mechanism comprising a magnetic seat facing the carrying platform;
a receiving cassette disposed below the magnetic seat, the magnetic seat being movable along the receiving cassette; and
a pulling mechanism comprising a gripper adjacent to the magnetic seat; wherein the pulling mechanism is configured to hold the connection member of the electronic module through the gripper and to move the gripper toward the magnetic seat, so that the connection member is separated from the electronic device and is attracted and positioned on the magnetic seat through the magnetically attractable portion;
wherein the magnetic seat is configured to move the connection member attracted thereby toward the receiving cassette so that the connection member is placed into the receiving cassette.

17. The processing system of claim 16, wherein, when the supply cassette is empty of the plurality of connection members, the supply cassette is detachable from the insertion device and mountable to the pull-out device for use as the receiving cassette.

18. The processing system according to claim 16, wherein, when the receiving cassette is fully filled with the plurality of connection members, the receiving cassette is detachable from the pull-out device and mountable to the insertion device for use as the supply cassette.

19. The processing system according to claim 16, wherein the receiving cassette has a rail groove that is recessed from a mouth thereof, and the magnetic seat is movable along the rail groove of the receiving cassette to move the connection member attracted thereby into the mouth of the receiving cassette, and wherein, when the magnetic seat moves away from the rail groove, the connection member disengages from the magnetic seat and falls into the receiving cassette.

20. The processing system according to claim 16, wherein a structure of the supply cassette is identical to a structure of the receiving cassette.
